(19) United States
(12) Patent Application Publication
(10) Pub. No.: US 2025/0301897 A1
(43) Pub. Date: Sep. 25, 2025

(54) DISPLAY APPARATUS

(71) Applicant: LG Display Co., Ltd., Seoul (KR)

(72) Inventors: Jeongmin PARK, Paju-si (KR); Sunggyu KIM, Paju-si (KR)

(73) Assignee: LG Display Co., Ltd., Seoul (KR)

(21) Appl. No.: 19/039,575

(22) Filed: Jan. 28, 2025

(30) Foreign Application Priority Data
Mar. 22, 2024 (KR) 10-2024-0040009

(51) Int. Cl. H10K 71/70; H10K 59/126; H10K 59/131; H10K 59/40

(52) U.S. Cl. CPC H10K 71/70; H10K 59/126; H10K 59/131; H10K 59/40

(57) ABSTRACT

A display apparatus can include a substrate having a display area and a first non-display area adjacent to the display area, a plurality of pixels and a camera hole that are disposed in the display area, a plurality of transistors included in each of the plurality of pixels, and a second non-display area between the display area and the camera hole. The second non-display area includes at least one crack detection pattern part. The crack detection pattern part includes a crack detection electrode and a crack detection line that surround the camera hole, and a crack detection signal line electrically connected to the crack detection electrode and the crack detection line.

### CROSS REFERENCE TO RELATED APPLICATION

The present application claims priority to Korean Patent Application No. 10-2024-0040009, filed in the Republic of Korea on Mar. 22, 2024, the entire contents of which are hereby expressly incorporated by reference into the present application.

### BACKGROUND

### Technical Field

The present specification relates to an apparatus and particularly to, for example, without limitation, a display apparatus that is capable of reducing or preventing cracks which can be caused by forming a camera hole of the display apparatus in which a camera hole area is formed in a display area and detecting the cracks.

### Discussion of the Related Art

Modern display apparatuses that can display various pieces of information and interact with users viewing the corresponding information need to have various sizes, shapes, and functions.

Examples of the display apparatus include a liquid crystal display apparatus (LCD), a field emission display apparatus (FED), an organic light emitting diode (OLED) display apparatus, etc.

The OLED display apparatus is self-luminous display apparatus and unlike the LCD, does not require a separate light source. Thus, lightweight and thin OLED display apparatuses can be manufactured. In addition, the OLED display apparatus is advantageous in terms of power consumption due to a low-voltage operation and also has excellent color expression, response speed, viewing angle, and contrast ratio (CR), and thus is researched as a next-generation display.

The OLED display apparatus uses a plurality of thin film transistors (or “TFT”) to control a current flowing in an organic light emitting diode to display an image.

The display apparatus is being developed by adding a camera, a speaker, and a sensor.

In particular, a hole in the display structure that forms a hole in a device so that a sensor such as a camera is disposed in a display area to improve or maximize the display area of the display apparatus is being applied.

The description provided in the discussion of the related art section should not be assumed to be prior art merely because it is mentioned in or associated with that section. The discussion of the related art section can include information that describes one or more aspects of the subject technology, and the description in this section does not limit the invention.

### SUMMARY OF THE DISCLOSURE

There is a limitation that cracks can occur in layers near the hole in a process of forming the hole in a display apparatus.

One or more embodiments of the present specification are directed to providing a display apparatus including a substrate having a through hole in a display area.

One or more embodiments of the present specification are also directed to providing a display apparatus that is capable of reducing or preventing cracks when implementing a through hole or rounded shape (curvature) on a substrate.

One or more embodiments of the present specification are also directed to providing a display apparatus that is capable of detecting cracks due to an external impact in an area near a through hole as cracks that can be caused due to a process of implementing the through hole or rounded shape (curvature) and the through hole are formed in a substrate.

The benefits of the present specification are not limited to the above-described benefits, and other benefits that are not mentioned will be able to be clearly understood by those skilled in the art from the following description.

A display apparatus according to an embodiment of the present specification can include a substrate including a display area and a first non-display area surrounding the display area, a plurality of pixels and a camera hole can be disposed in the display area, each of the plurality of pixels can include a plurality of transistors, a second non-display area can be disposed between the display area and the camera hole, the second non-display area can include a plurality of pattern parts and a crack detection pattern part, the crack detection pattern part can include a crack detection electrode and a crack detection line that surround the camera hole, and the crack detection electrode and the crack detection line can be electrically connected to a crack detection signal line.

A display apparatus according to an embodiment of the present specification can include a display area and a first non-display area surrounding the display area on a substrate, a plurality of pixels and a camera hole can be disposed in the display area, a second non-display area can be disposed between the display area and the camera hole, the second non-display area can at least include a first crack detection pattern part and a second crack detection pattern part, the first crack detection pattern part and the second crack detection pattern part can each include a crack detection electrode and a crack detection line, and lengths of crack detection electrodes of the first crack detection pattern part and the second crack detection pattern part can be different.

In the display apparatus according to the embodiments of the present specification, it is possible to reduce or prevent cracks that can occur when forming the through hole for a camera and a sensor that are disposed in the display area or occurs near the through hole by an external impact.

In the display apparatus according to the embodiments of the present specification, it is possible to detect cracks that can be caused by forming the through hole disposed in the display area and where cracks due to an external impact have occurred near the through hole.

The effects of the present specification are not limited to the above-described effects, and other effects that are not described will be able to be clearly understood by those skilled in the art from the following description.

Since the contents of the disclosure described in the above-described limitations to be solved, means to solve the limitations, and effects do not specify the essential features of the claims, the scope of the claims is not limited by the items described in the contents of the specification.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view showing a display apparatus according to one or more embodiments of the present specification.

FIG. 2 is a cross-sectional view showing one example of a cross section along line 2-2′ in FIG. 1 according to an embodiment of the present specification.

FIG. 3 is an enlarged plan view of area P in FIG. 1 according to an embodiment of the present specification.

FIG. 4 is a schematic view showing a configuration of routing lines disposed in area PH in FIG. 1 according to an embodiment of the present specification.

FIG. 5 is a cross-sectional view showing one embodiment of the present specification as a cross section along line 5-5′ in FIG. 4.

FIG. 6 is a cross-sectional view showing another embodiment of the present specification as a cross section of 5-6′ in FIG. 4.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Advantages and features of the present specification and methods for achieving them will become clear with reference to embodiments described below in detail in conjunction with the accompanying drawings. However, the present specification is not limited to the embodiments disclosed below but can be implemented in various different forms, these embodiments are merely provided to make the disclosure of the present specification complete and fully inform those skilled in the art to which the present specification pertains of the scope of the present specification, and the present specification is only defined by the scope of the appended claims.

Since shapes, sizes, ratios, angles, numbers, and the like disclosed in the drawings for describing the embodiments of the present specification are illustrative, the present specification is not limited to the illustrated items. The same reference number denotes the same components throughout the specification. In addition, in describing the present specification, when it is determined that the detailed description of a related known technology can unnecessarily obscure the gist of the present specification, detailed description thereof will be omitted or can be briefly provided. When “comprises,” “has,” “consists of,” etc. described in the present specification are used, other parts can be added unless “only” is used. When a component is expressed in the singular, it includes a case in which the component is provided as a plurality of components unless specifically stated otherwise. Further, the term “can” fully encompasses all the meanings and coverages of the term “can.”

Any implementation described herein as an “example” is not necessarily to be construed as preferred or advantageous over other implementations.

In construing a component, the component is construed as including the margin of error even when there is no separate explicit description about the margin of error.

When the positional relationship is described, for example, when the positional relationship between two parts is described using “on,” “above,” “under,” “under,” “next to,” or the like, one or more other parts can be located between the two parts unless “immediately” or “directly” is used.

When the temporal relationship is described, when the temporal relationship is described using the term “after,” “subsequently,” “then,” “before,” or the like, it can also include a non-consecutive case unless the term “immediately” or “directly” is used.

Although terms such as first and second are used to describe various components, these components are not limited by these terms. These terms are only used to distinguish one component from another component. Therefore, a first component described below can be a second component within the technical idea of the present specification.

In the description of the components of the present specification, terms such as first, second, A, B, (a), and (b) can be used. These terms are only for the purpose of distinguishing one component from another component, and the nature, sequence, order, or the like of the corresponding component is not limited by these terms. When a certain component is described as being “connected,” “coupled,” or “joined” to another component, the certain component can be connected or joined directly to another component, but it can be understood that other components can be “interposed” between the components, which can be connected or coupled indirectly, unless otherwise stated specially.

It can be understood that the term “at least one” includes any combination of one or more of associated components. For example, the term “at least one of first, second, and third components” can include not only the first, second, or third component, but also any combination of two or more of the first, second, and third components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

In the present specification, “apparatus” can include a display apparatus, such as a liquid crystal module (LCM) and an organic light emitting display module (OLED module), including a display panel and a driver for driving the display panel. In addition, the apparatus can also include a set electronic apparatus or a set device (or a set apparatus), such as a laptop computer, a television, a computer monitor, a vehicle or automotive apparatus, a mobile electronic apparatus of a smartphone, an electronic pad, etc., which is a complete product or final product including an LCM, an OLED module, etc.

Therefore, the apparatus in the present specification can include a display apparatus such as an LCM or OLED module and a set apparatus that is an application product or end-consumer apparatus including an LCM or OLED module, etc.

In addition, in some embodiments, an LCM or OLED module that is composed of a display panel, a driving unit, etc. can be referred to as a “display apparatus,” and an electronic apparatus as a finished product including an LCM or OLED module can be separately referred to as a “set apparatus.” For example, a display apparatus can include a display panel of an LCD or an OLED display, and a source printed circuit board (PCB) as a control unit for driving the display panel. The set apparatus can further include a set PCB as a set control unit electrically connected to the source PCB to drive the entirety of the set device.

The display panel used in the embodiments of the present specification can be any type of display panel, such as an OLED display panel or an electroluminescent display panel. However, embodiments are not limited thereto. For example, the display panel can be a display panel that can generate sound by being vibrated by a vibration device according to an embodiment of the present specification. The display panel applied to the display apparatus according to embodiments of the present specification is not limited to the shape or size of the display panel.

Features of various embodiments of the present specification can be coupled or combined partially or entirely, and various technological interworking and driving are possible, and the embodiments can be implemented independently of each other or implemented together in an associated relationship. All the components of each display apparatus according to all embodiments of the present disclosure are operatively coupled and configured.

Hereinafter, embodiments of the present specification will be described through the accompanying drawings and embodiments as follows. Scales of components shown in the drawings differ from the actual scale for convenience of description, and thus are not limited to the scales shown in the drawings.

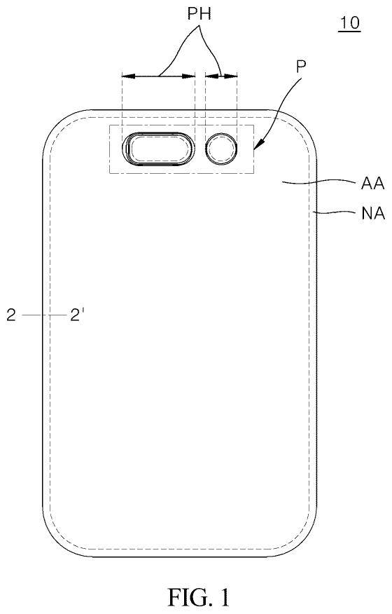

FIG. 1 is a schematic plan view showing one example of a display apparatus according to one or more embodiments of the present specification.

Referring to FIG. 1, a display apparatus 10 can include a plurality of areas. For example, the display apparatus 10 includes one or more display areas AA (or active areas) that are an area in which a picture image is displayed, and a pixel array PXL is formed inside the display area AA. First non-display areas NA (or non-active areas) in which the picture image is not displayed can include a driving circuit part and a dam part and can be provided on one side surface of the display area AA. For example, the first non-display area NA can be adjacent to at least one side surfaces of the display area AA.

The first non-display area NA can surround the substantially rectangular display area AA and can be positioned outside the display area AA. However, it can be understood that shapes of the display area AA and the arrangement of the first non-display area NA adjacent to the display area AA are not specifically limited to the example display apparatus 10. The display area AA and the first non-display area NA can have any shape of the display apparatus 10. Examples of these shapes can include a pentagon, hexagon, circle, oval, etc., and the embodiments of the present specification are not limited thereto.

Each pixel PXL of the display area AA can include sub-pixels, and the sub-pixel can display colors of red (R), green (G), blue (B), and white (W). In addition, each of the pixel PXL and the sub-pixel can be associated with a pixel circuit including at least one transistors (thin film transistors (TFTs)) manufactured on a substrate of the display apparatus 10. Each pixel circuit can be electrically connected to a gate line and a data line to communicate with at least one driving circuits, for example, a gate driver (GIP) and a data driver (D-IC) that are positioned in the first non-display area NA of the display apparatus 10.

The at least one driving circuits can be implemented using TFTs formed in the first non-display area NA. For example, the gate driver (GIP) can be implemented using a plurality of TFTs on the substrate of the display apparatus 10. Non-limiting examples of circuits that can be implemented as TFTs on the substrate can include an inverter circuit, a multiplexer, an electrostatic discharge (ESD) circuit, etc., and the embodiments of the present disclosure are not limited thereto.

Some driving circuits can be provided as integrated circuit (IC) chips and mounted in the first non-display area NA of the display apparatus 10 using chip-on-glass (COG) or other similar methods. In addition, some driving circuits can be mounted on another substrate and coupled to connection interfaces (pads/bumps, pins) disposed in the first non-display area NA using a printed circuit such as a flexible PCB, a COF, a tape-carrier-package (TCP), or other suitable technologies.

In the first non-display area NA, crack detection lines that detect cracks occurring in a second non-display area PH and cracks transmitted from the outside of the display panel can be disposed to surround an outer edge of the display area AA, and crack detection pads can be disposed in an area in which FPCBs or driver ICs are disposed as much as possible.

The crack detection pad can apply a predetermined level of power and compare an input value with an output value. A resistance level of crack detection lines can be identified by a difference between the input and output values, and based on this, cracks can be detected.

In the embodiments of the present specification, at least two different types of TFTs are used in a TFT substrate for display. The types of TFTs employed in some pixel circuits and some driving circuits can vary depending on the requirements of the display.

For example, the pixel circuit can be implemented using a TFT having an oxide active layer (oxide TFT), and the driving circuit can be implemented using a TFT having a low-temperature polycrystalline silicon active layer (LTPS TFT) and a TFT having an oxide active layer. Unlike LTPS TFTs, oxide TFTs do not undergo a threshold voltage (Vth) fluctuation limitation from pixel-to-pixel. A uniform threshold voltage (Vth) can be acquired in an array of pixel circuits for display. The limitation of uniformity of threshold voltage (Vth) between TFTs implementing the driving circuit will have less direct influence on the uniformity of luminance of pixels.

The driving circuits (e.g., GIP) can have gate drive ICs embedded inside the display panel to reduce the cost due to a reduction in the number of drive ICs and provide high-speed scan signals to the display area of the display panel.

Using the driving circuits on the substrate implemented using LTPS TFTs, signals and pieces of data can be provided to pixels using a higher clock than a case in which all TFTs in the TFT panel are formed as oxide TFTs. Therefore, a display capable of a high-speed operation can be provided without spots such as Mura. For example, the advantages of oxide TFT and LTPS TFT can be combined with the design of the TFT panel, and oxide TFT and LTPS TFT can be used by being selected according to each advantage.

The display area AA can include at least one second non-display area PH and include a circular or oval through hole H.

In the second non-display area PH, sensors such as a camera, a distance detection sensor, and a facial recognition sensor can be disposed.

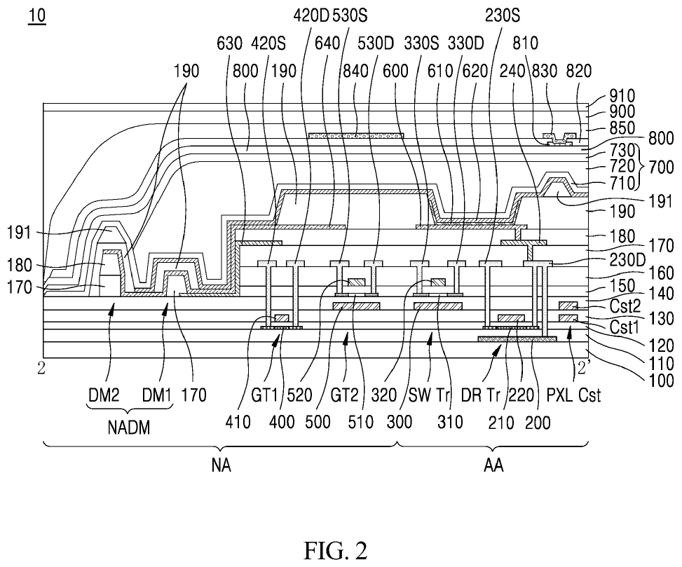

FIG. 2 is a schematic cross-sectional view showing one example of a cross section along line 2-2′ in FIG. 1.

Referring to FIG. 2, the substrate 100 of the display apparatus according to one or more embodiments of the present specification can include a first substrate, a second substrate, and an intermediate layer between the first substrate and the second substrate.

The first substrate and the second substrate can be made of at least one of polyimide, polyethersulfone, polyethylene terephthalate, and polycarbonate, and the embodiments of the present specification are not limited thereto. When the substrate is made of a plastic material, the manufacturing process of the display apparatus can be performed in a state in which a support substrate made of glass is disposed under the substrate, and the support substrate can be released after the manufacturing process of the display apparatus is completed. In addition, after the support substrate is released, a back plate (or plate) for supporting the substrate can be disposed under the substrate. When the substrate is made of a plastic material, moisture can penetrate the substrate and then the thin film transistor or a light emitting element layer, thereby deteriorating or lowering the performance of the display apparatus.

The display apparatus according to the embodiment of the present specification can be composed of two substrates of the first substrate and the second substrate that are made of a plastic material to reduce or prevent a deterioration or lowering of performance of the display apparatus due to moisture penetration. In addition, by forming an intermediate layer, which is an inorganic film, between the first substrate and the second substrate, it is possible to block moisture from penetrating the substrate, thereby improving the performance reliability of products. The intermediate layer can be made of an inorganic film. For example, the intermediate layer can be formed of a single layer or multiple layers of silicon nitride (SiNₓ) or silicon oxide (SiOₓ), but is not limited thereto.

The display apparatus formed on the substrate 100 can include a plurality of areas. In the present specification, the display apparatus is composed of the display area AA and the first non-display area NA, but is not limited thereto.

A buffer layer 101 formed of a single layer or multiple layers of silicon nitride (SiNₓ) or silicon oxide (SiOₓ) can be disposed on one surfaces of the display area AA and the first non-display area NA on the substrate 100. The buffer layer 101 can increase adhesive strength between layers formed on the buffer layer 101 and the substrate 100 and serve to block any type of defect factor, such as an alkaline component leaking from the substrate 100. In addition, the buffer layer 101 can delay the diffusion of moisture and/or oxygen penetrating the substrate 100.

The buffer layer 101 can be omitted based on the type and material of the substrate, the structure and type of the thin film transistor, etc.

Transistors of the display area AA and the first non-display area NA can be formed on the buffer layer 101. The transistors of the display area AA can include a switching transistor SW Tr and a driving transistor DR Tr for driving a sub-pixel, and the transistors of the first non-display area NA can include a first gate driving transistor GT1 and a second gate driving transistor GT2 for driving the gate driver (GIP).

A light shielding layer 200 can be disposed on the buffer layer 101 to overlap at least a portion of the driving transistor DR Tr.

The light shielding layer 200 can shield light directed to a first semiconductor layer 210 of the driving transistor DR Tr and connected to a first drain electrode 230D, thereby reducing or preventing a phenomenon in which parasitic carriers accumulate in the first semiconductor layer 210 to quickly increase a drain current or a change in threshold voltage due to such a phenomenon.

The light shielding layer 200 can be formed of a single layer or multiple layers having at least one of titanium (Ti), molybdenum (Mo), copper (Cu), aluminum (Al), silver (Ag), chromium (Cr), gold (Au), neodymium (Nd), and nickel (Ni), and the embodiments of the present specification are not limited thereto.

A first insulating layer 110 can be disposed on the light shielding layer 200. The first insulating layer 110 can be made of an insulating material such as silicon nitride (SiNₓ) or silicon oxide (SiOₓ) and can also be made of an insulating inorganic material or organic material, and the embodiments of the present specification are not limited thereto.

The first semiconductor layer 210 of the driving transistor DR Tr of the display area AA and a second semiconductor layer 400 of the first gate driving transistor GT1 of the first non-display area NA can be disposed on the first insulating layer 110, and the first semiconductor layer 210 can overlap the light shielding layer 200.

The first semiconductor layer 210 and the second semiconductor layer 400 can be made of low temperature polycrystalline silicon (LTPS).

The first gate insulating layer 120 can be disposed on the first semiconductor layer 210 and the second semiconductor layer 400. The first gate insulating layer 120 can be made of an insulating material such as silicon nitride (SiNₓ) or silicon oxide (SiOₓ) and can also be made of an insulating inorganic material or organic material, and the embodiments of the present specification are not limited thereto.

A first gate electrode 220 and a second gate electrode 410 can be disposed on the first gate insulating layer 120 to overlap the first semiconductor layer 210 and the second semiconductor layer 400, and the first gate electrode 220 and the second gate electrode 410 can be made of at least one materials of silver (Ag), molybdenum (Mo), copper (Cu), titanium (Ti), aluminum (Al), chromium (Cr), gold (Au), nickel (Ni), neodymium (Nd), tungsten (W), and gold (Au), and the embodiments of the present specification are not limited thereto.

A first capacitor electrode Cst1 of a capacitor PXL Cst included in a sub-pixel can be formed in the same or substantially same process as the first gate electrode 220 and the second gate electrode 410.

A second insulating layer 130 can be disposed on the first gate electrode 220, the second gate electrode 410, and the first capacitor electrode Cst1.

The second insulating layer 130 can be made of an insulating material such as silicon nitride (SiNₓ) or silicon oxide (SiOₓ) and can also be made of an insulating inorganic material or organic material, and the embodiments of the present specification are not limited thereto.

A second capacitor electrode Cst2 of the sub-pixel capacitor PXL Cst can be disposed on the second insulating layer 130. The second capacitor electrode Cst2 can be disposed to overlap the first capacitor electrode Cst1 and made of the same or substantially same material as the first capacitor electrode Cst1.

A first metal layer 300 overlapping the switching transistor SW Tr of the sub-pixel and a second metal layer 500 overlapping the second gate driving transistor GT2 can be disposed by being formed on the second insulating layer 130.

The first metal layer 300 and the second metal layer 500 can be driven by lower gate electrodes of the switching transistor SW Tr and the second gate driving transistor GT2, respectively, or used as light shielding layers that shield light reflected to a third semiconductor layer 310 and a fourth semiconductor layer 510 of the switching transistor SW Tr and the second gate driving transistor GT2, and the embodiments of the present specification are not limited thereto.

A third insulating layer 140 can be disposed on the second capacitor electrode Cst2, the first metal layer 300, and the second metal layer 500.

The third insulating layer 140 can be made of an insulating material such as silicon nitride (SiNₓ) or silicon oxide (SiOₓ) and can also be made of an insulating organic material or the like, and the embodiments of the present specification are not limited thereto.

The third semiconductor layer 310 of the switching transistor SW Tr of the display area AA and the fourth semiconductor layer 510 of the second gate driving transistor GT2 of the first non-display area NA can be disposed on the third insulating layer 140.

The third semiconductor layer 310 and the fourth semiconductor layer 510 can be made of a metal oxide semiconductor, for example, one of IGZO, IZO, IGTO, and IGO, but are not limited thereto.

The metal oxide semiconductor can have improved conductive properties by a doping process that injects impurities and include a channel area in which a channel through which electrons or holes move is formed, and a source area and a drain area that are conductive areas at both sides of the channel area. A source electrode and a drain electrode can be connected to the source area and the drain area.

The second gate insulating layer 150 can be disposed on the third semiconductor layer 310 and the fourth semiconductor layer 510. The second gate insulating layer 150 can be disposed between the third semiconductor layer 310 and the fourth semiconductor layer 510 and between the third gate electrode 320 and the fourth gate electrode 520 to insulate the third semiconductor layer 310 and the fourth semiconductor layer 510, and the third gate electrode 320 and the fourth gate electrode 520.

The second gate insulating layer 150 can be made of an insulating inorganic material such as silicon nitride (SiNₓ) or silicon oxide (SiOₓ) and can also be made of an insulating organic material, but is not limited thereto.

The third gate electrode 320 and the fourth gate electrode 520 can be disposed on the second gate insulating layer 150 to overlap the third semiconductor layer 310 and the fourth semiconductor layer 510.

The third gate electrode 320 and the fourth gate electrode 520 can be formed of a single layer or multiple layers made of one of silver (Ag), molybdenum (Mo), copper (Cu), titanium (Ti), aluminum (Al), chromium (Cr), gold (Au), nickel (Ni), neodymium (Nd), tungsten (W), and gold (Au), or an alloy thereof, but is not limited thereto.

A fourth insulating layer 160 can be disposed on the third gate electrode 320 and the fourth gate electrode 520.

The fourth insulating layer 160 can be made of an insulating inorganic material such as silicon nitride (SiNₓ) and silicon oxide (SiOₓ) or made of at least one of organic insulating materials such as benzocyclobutene (BCB), an acrylic resin, an epoxy resin, a phenolic resin, a polyamide resin, or a polyimide resin, and the embodiments of the present specification are not limited thereto.

On the fourth insulating layer 160, a first source electrode 230S and a first drain electrode 230D that are connected to the first semiconductor layer 210, a second source electrode 420S and a second drain electrode 420D that are connected to the second semiconductor layer 400, a third source electrode 330S and a third drain electrode 330D that are connected to the third semiconductor layer 310, and a fourth source electrode 530S and a fourth drain electrode 530D that are connected to the fourth semiconductor layer 510 can be disposed.

The first source electrode 230S, the first drain electrode 230D, the second source electrode 420S, and the second drain electrode 420D are connected to the first semiconductor layer 210 and the second semiconductor layer 400 through contact holes formed in the first gate insulating layer 120, the second insulating layer 130, the third insulating layer 140, the second gate insulating layer 150, and the fourth insulating layer 160.

The third source electrode 330S, the third drain electrode 330D, the fourth source electrode 530S, and the fourth drain electrode 530D are connected to the third semiconductor layer 310 and the fourth semiconductor layer 510 through contact holes formed in the second gate insulating layer 150 and the fourth insulating layer 160.

The first source electrode 230S, the first drain electrode 230D, the second source electrode 420S, the second drain electrode 420D, the third source electrode 330S, the third drain electrode 330D, the fourth source electrode 530S, and the fourth drain electrode 530D can be formed through the same or substantially same process and can be made of at least one of silver (Ag), molybdenum (Mo), copper (Cu), titanium (Ti), aluminum (Al), chromium (Cr), gold (Au), nickel (Ni), neodymium (Nd), tungsten (W), and gold (Au).

A first planarization layer 170 can be disposed on the first source electrode 230S, the first drain electrode 230D, the second source electrode 420S, the second drain electrode 420D, the third source electrode 330S, the third drain electrode 330D, the fourth source electrode 530S, and the fourth drain electrode 530D.

The first planarization layer 170 can be formed of an organic insulating layer such as polyacrylate and polyimide, thereby reducing a step due to lines and contact holes formed thereunder.

A connection electrode 240 for connecting the first drain electrode 230D to an anode electrode 600 can be disposed on the first planarization layer 170.

The connection electrode 240 can be electrically connected to the first drain electrode 230D through a hole formed in the first planarization layer 170.

The connection electrode 240 can be made of at least one of titanium (Ti), molybdenum (Mo), copper (Cu), aluminum (Al), silver (Ag), chromium (Cr), gold (Au), neodymium (Nd), nickel (Ni), or an alloy thereof, and the embodiments of the present specification are not limited thereto.

A first line 630 can be disposed by being formed in the first non-display area NA in the same or substantially same process as the connection electrode 240.

The first line 630 can be one of lines for transmitting a voltage applied to a cathode electrode 620 as a low-potential voltage in the first non-display area NA.

A second planarization layer 180 can be disposed on the connection electrode 240 and the first line 630. The second planarization layer 180 can be formed of an organic insulating layer such as polyacrylate and polyimide, and the embodiments of the present specification are not limited thereto.

The anode electrode 600 can be disposed on the second planarization layer 180. The anode electrode 600 can be electrically connected to the connection electrode 240 through a hole formed in the second planarization layer 180.

A second line 640 can be formed in the first non-display area NA in the same or substantially same process as the process of forming the anode electrode 600. The second line 640 can be disposed to overlap portions of the first gate driving transistor GT1 and the second gate driving transistor GT2 and connected to the first line 630 disposed in the first non-display area NA to apply a low-potential voltage to the cathode electrode 620.

The anode electrode 600 and the second line 640 can be made of at least one of silver (Ag), aluminum (Al), gold (Au), molybdenum (Mo), tungsten (W), chromium (Cr), lead (Pd), indium tin oxide (ITO), indium zinc oxide (IZO), or an alloy thereof, and the embodiments of the present specification are not limited thereto.

A bank 190 can be disposed on the anode electrode 600, the second line 640, and the second planarization layer 180.

The bank 190 can separate a plurality of sub-pixels SP, thereby reducing or minimizing light bleeding and reducing or preventing color mixing occurring at any viewing angle.

The bank 190 can expose the anode electrode 600 corresponding to the light emitting area and cover an end portion of the anode electrode 600.

The bank 190 can be made of at least one of an inorganic insulating material such as silicon nitride (SiNₓ) or silicon oxide (SiOₓ), or an organic insulating material such as BCB, an acrylic resin, an epoxy resin, a phenolic resin, a polyamide resin, or a polyimide resin, but is not limited thereto.

A spacer 191 can be further disposed on the bank 190. The spacer 191 can support a gap between the substrate 100 on which the light emitting element layer 610 is formed and an upper substrate, thereby reducing or minimizing damage to elements inside the display panel when an external physical impact occurs. The spacer 191 can be made of the same or substantially same material as the bank 190 and formed simultaneously with the bank 190, but is not limited thereto.

The light emitting element layer 610 can be disposed on an opening of the bank 190 that exposes the anode electrode 600. The light emitting element layer 610 can include at least one organic light emitting layers of a red light emitting layer, a green light emitting layer, a blue light emitting layer, and a white light emitting layer to emit light of a specific color. In addition, the light emitting element layer 610 can further include a hole injection layer, a hole transport layer, an electron transport layer, and an electron injection layer in addition to the organic light emitting layer, but is not limited thereto.

The hole injection layer, the hole transport layer, the electron transport layer, and the electron injection layer with different thicknesses and materials can be disposed in each sub-pixel or disposed commonly over the entire display area AA.

When the light emitting element layer 610 is disposed commonly over the entire display area AA, a color filter can be disposed above the light emitting element layer 610 to overlap the light emitting area of the sub-pixel in order to emit light corresponding to each sub-pixel.

The cathode electrode 620 can be disposed on the light emitting element layer 610. The cathode electrode 620 can supply electrons to the light emitting element layer 610 and can be made of a conductive material with a low work function.

When the display apparatus 10 is a top-emission type, the cathode electrode 620 can be disposed using a transparent conductive material that transmits light. For example, the cathode electrode 620 can be made of at least one of ITO and IZO, but is not limited thereto.

In addition, the cathode electrode 620 can be disposed using a semitransparent conductive material that transmits light. For example, the cathode electrode 620 can be made of at least one of alloys such as LiF/Al, CsF/Al, Mg:Ag, Ca/Ag, Ca:Ag, LiF/Mg:Ag, LiF/Ca/Ag, and LiF/Ca:Ag, but is not limited thereto.

When the display apparatus 10 is a bottom-emission type, the cathode electrode 620 can be disposed using an opaque conductive material as a reflective electrode that reflects light. For example, the cathode electrode 620 can be made of at least one of silver (Ag), aluminum (Al), gold (Au), molybdenum (Mo), tungsten (W), chromium (Cr), or an alloy thereof.

A plurality of driving circuit parts and dams NADM of the first non-display area are disposed in the first non-display area NA of the display apparatus 10.

The first non-display area NA can be an area in which a connection part that electrically connects the cathode electrode 620 to lines through which a voltage is applied to the cathode electrode 620, and the display apparatus 10 using the dams NADM of the plurality of non-display areas are sealed.

The first insulating layer 110, the first gate insulating layer 120, the second insulating layer 130, and the third insulating layer 140 of the display area AA can be disposed to extend in the first non-display area NA.

The lines can be disposed in the first non-display area NA so that power voltages and touch signals that are applied from the FPCB of the display apparatus 10 are connected to the display panel through the lines.

The lines can be disposed to be in contact with the side surfaces of the fourth insulating layer 160 and the second gate insulating layer 150 and to extend between a first dam DM1 of the first non-display area NA and the third insulating layer 140.

The first dam DM1 can be stacked by being made of the same or substantially same material and formed in the same or substantially same process as the first planarization layer 170 and the bank 190.

A second dam DM2 can be stacked by being made of the same or substantially same material and formed in the same or substantially same process as the first planarization layer 170, the second planarization layer 180, the bank 190, and the spacer 191.

The first dam DAM1 and the second dam DAM2 can have a first height and a second height, respectively, and surround the display area AA.

The second height can be formed to be higher than the first height. Even when a second encapsulation layer 720 goes beyond the first dam DM1 of a second dam part, the second encapsulation layer 720 may not be formed outside the second dam DM2 due to the second dam DM2.

A first encapsulation layer 710 and a third encapsulation layer 730 can be disposed to extend to an outer portion beyond the second dam DM2.

The second line 640 can be disposed to extend between the first planarization layer 170 and the bank 190 of the first dam DM1 and between the second planarization layer 180 and the bank 190 of the second dam DM2.

The cathode electrode 620 can extend to an area between the first dam DM1 and the second dam DM2 and can be electrically connected to the first line 630 and the second line 640.

An encapsulation layer 700 can be disposed on the cathode electrode 620 of the display area AA, the cathode electrode 620 of the first non-display area NA, and the second dam DM2.

The encapsulation layer 700 can protect the display apparatus 10 from external moisture, oxygen, or foreign substances. For example, the encapsulation layer 700 can reduce or prevent the penetration of oxygen and moisture from the outside to reduce or prevent oxidation of the light emitting material and the electrode material.

The encapsulation layer 700 can be made of a transparent material so that light emitted from the light emitting element layer 610 can be transmitted.

The encapsulation layer 700 can include the first encapsulation layer 710, the second encapsulation layer 720, and the third encapsulation layer 730 that block the penetration of moisture or oxygen, and the embodiments of the present specification are not limited thereto. The first encapsulation layer 710, the second encapsulation layer 720, and the third encapsulation layer 730 can have a sequentially stacked structure, and the embodiments of the present specification are not limited thereto.

The first encapsulation layer 710 and the third encapsulation layer 730 can be made of at least one inorganic material of silicon nitride (SiNₓ), silicon oxide (SiOₓ), or aluminum oxide (Al_{y}O_{z}), but are not limited thereto.

The second encapsulation layer 720 can cover foreign substances or particles that can occur during the manufacturing process. In addition, the second encapsulation layer 720 can planarize a surface of the first encapsulation layer 710.

The second encapsulation layer 720 can be made of an organic material, for example, a polymer such as silicon oxycarbon (SiOC_{z}), epoxy, polyimide, polyethylene, or acrylate, but is not limited thereto.

A touch buffer layer 800 can be disposed on the third encapsulation layer 730. The touch buffer layer 800 can be disposed on the entire surface of the display area AA and the first non-display area NA and disposed to extend to a pad part. The touch buffer layer 800 can be a first insulating layer and is not limited to the term.

The touch buffer layer 800 can be made of at least one inorganic material of silicon nitride (SiNₓ), silicon oxide (SiOₓ), or aluminum oxide (Al_{y}O_{z}), and is not limited thereto.

A first touch electrode 810 can be disposed on the touch buffer layer 800.

The touch operation can be driven by a plurality of detection electrodes and a plurality of driving electrodes that are disposed in the display area AA. The detection electrode includes a plurality of sub-detection electrodes Rx that extend in a first direction and are disposed at a predetermined interval in a second direction. The plurality of detection electrodes can be formed continuously without disconnection in the first direction.

The plurality of driving electrodes include a plurality of sub-driving electrodes Tx that extend in the second direction and are disposed at a predetermined interval in the first direction. The plurality of sub-driving electrodes Tx can be electrically connected in the second direction.

When the plurality of sub-detection electrodes Rx and the plurality of sub-driving electrodes Tx are formed on the same layer, the plurality of sub-driving electrodes Tx can be electrically connected by a bridge pattern.

The plurality of sub-detection electrodes Rx and the plurality of sub-driving electrodes Tx can have a metal mesh structure.

In addition, the plurality of sub-detection electrodes Rx can be electrically connected by the bridge pattern, and the plurality of sub-driving electrodes Tx can be electrically connected by being formed continuously without disconnection.

The first touch electrode 810 can electrically connect the plurality of sub-detection electrodes Rx or the plurality of sub-driving electrodes Tx.

The first touch electrode 810 can have a single-layer or multilayered structure made of a metallic material such as molybdenum (Mo), silver (Ag), titanium (Ti), copper (Cu), aluminum (Al), titanium/aluminum/titanium (Ti/Al/Ti), molybdenum/aluminum/molybdenum (Mo/Al/Mo), but is not limited thereto.

A touch insulating layer 820 can be disposed on the first touch electrode 810. The touch insulating layer 820 can be disposed on the entire surface of the display area AA and the first non-display area NA and disposed to extend to the pad part. The touch insulating layer 820 can be a second insulating layer and is not limited to the term.

The touch insulating layer 820 can be made of at least one inorganic material of silicon nitride (SiNₓ), silicon oxide (SiOₓ), or aluminum oxide (Al_{y}O_{z}), and is not limited thereto.

A second touch electrode 830 can be disposed on the touch insulating layer 820. The second touch electrode 830 can be a plurality of sub-detection electrodes Rx or a plurality of sub-driving electrodes Tx for touch driving.

In addition, the first touch electrode 810 can be a bridge electrode for electrically connecting the second touch electrodes 830 spaced apart from each other, but is not limited thereto.

A touch line 840 for transmitting a touch driving signal to the first non-display area NA can be disposed in the same or substantially same process as the process of forming the second touch electrode 830.

The touch line 840 can overlap the first gate driving transistor GT1 or the second gate driving transistor GT2 and can be disposed to extend to the pad part.

The second touch electrode 830 and the touch line 840 can have a single-layer or multilayered structure made of a metallic material such as molybdenum (Mo), silver (Ag), titanium (Ti), copper (Cu), aluminum (Al), titanium/aluminum/titanium (Ti/Al/Ti), molybdenum/aluminum/molybdenum (Mo/Al/Mo), but are not limited thereto.

A third planarization layer 850 can be disposed on the second touch electrode 830 and the touch line 840.

The third planarization layer 850 can cover and planarize the second touch electrode 830, the touch line 840, and the touch insulating layer 820. In addition, the third planarization layer 850 can be made of at least one organic insulating materials such as BCB, an acrylic resin, an epoxy resin, a phenolic resin, a polyamide resin, or a polyimide resin, but is not limited thereto.

An adhesive layer 900 and a cover window 910 can be disposed on the third planarization layer 850.

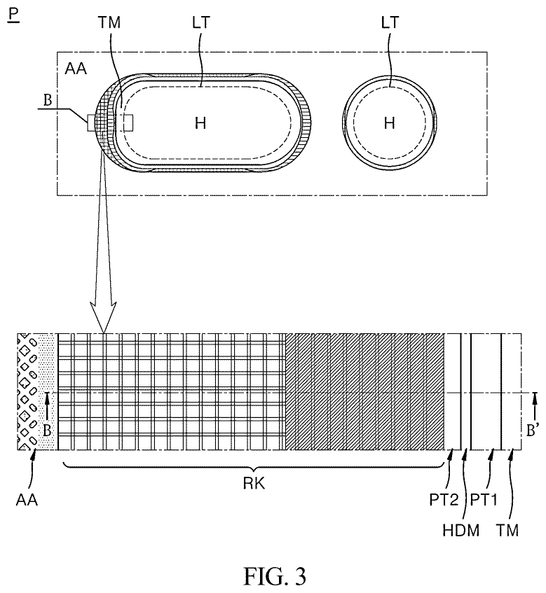

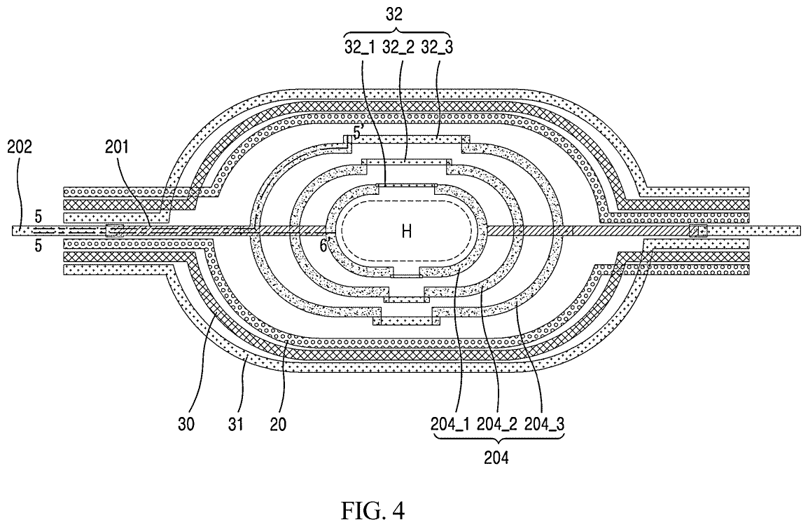

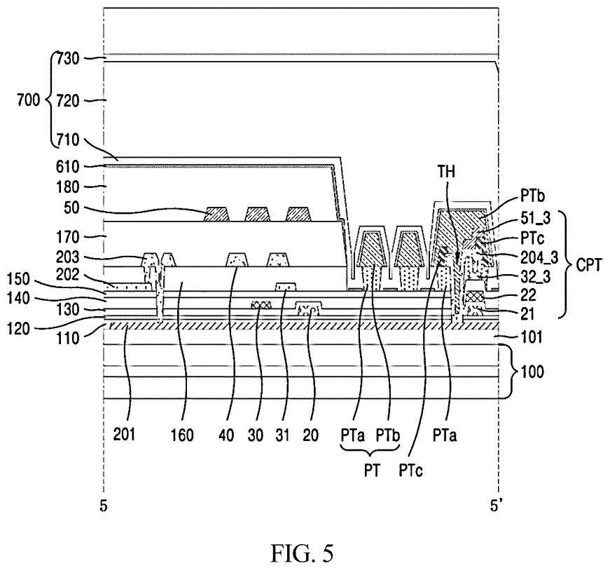

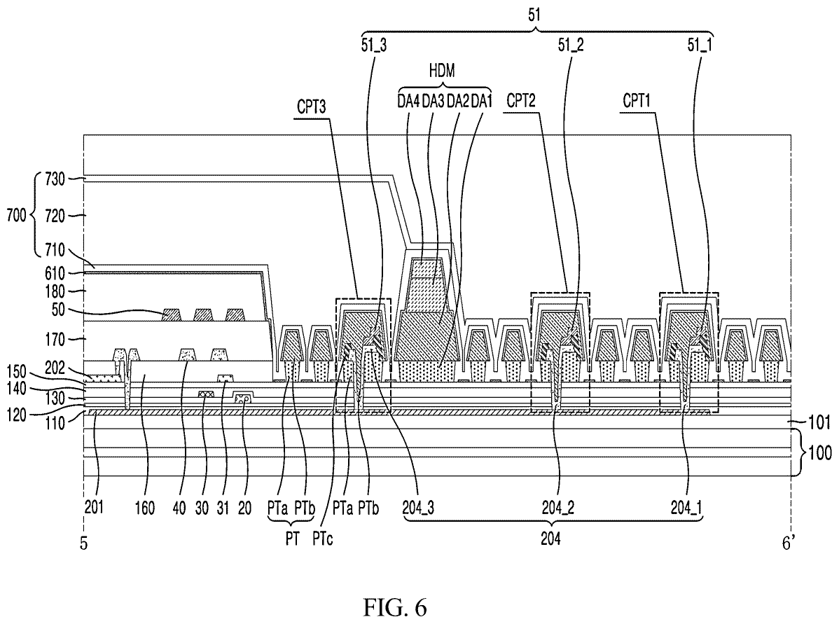

A configuration of the second non-display area PH shown in FIG. 1 will be described in detail with reference to FIGS. 3 to 6. FIG. 3 is an enlarged plan view of area P in FIG. 1 according to an embodiment of the present specification. FIG. 4 is a schematic view showing a configuration of routing lines disposed in area PH in FIG. 1 according to an embodiment of the present specification. FIG. 5 is a cross-sectional view showing one embodiment of the present specification as a cross section along line 5-5′ in FIG. 4. FIG. 6 is a cross-sectional view showing another embodiment of the present specification as a cross section of 5-6′ in FIG. 4.

Referring to FIGS. 3 to 6, to arrange a camera and a sensor in the display area AA, the second non-display area PH includes a through hole H, a trimming margin part TM surrounding the through hole H, a first pattern structure PT1, a hole dam HDM, a second pattern structure PT2, and a routing line area RK.

The through hole H can be positioned in a central portion of the second non-display area PH and formed to physically pass through from the substrate 100 to the third planarization layer 850. A camera, a sensor, and a light source can be disposed in a lower portion of the through hole H, and light can easily be transmitted above the camera or sensor by the through hole H.

In the routing line area RK, routing lines for electrically connecting lines connected to sub-pixels of the display area AA through the second non-display area PH are disposed.

A first routing line 20 can be made of the same or substantially same material as the material of forming the first gate electrode 220, the second gate electrode 410, and the first capacitor electrode Cst1 in the same or substantially same process on the first gate insulating layer 120 disposed to extend to the second non-display area PH, and the embodiments of the present specification are not limited thereto.

A second routing line 30 can be made of the same or substantially same material as the material of forming the second capacitor electrode Cst2 in the same or substantially same process on the second insulating layer 130 disposed to extend to the second non-display area PH, and the embodiments of the present specification are not limited thereto.

A third routing line 31 can be made of the same or substantially same material as the material of forming the third gate electrode 320 and the fourth gate electrode 520 in the same or substantially same process on the second gate insulating layer 150, and the embodiments of the present specification are not limited thereto.

A fourth routing line 40 can be formed in the same or substantially same process as the first source electrode 230S, the first drain electrode 230D, the second source electrode 420S, the second drain electrode 420D, the third source electrode 330S, the third drain electrode 330D, the fourth source electrode 530S, and the fourth drain electrode 530D on the fourth insulating layer 160 disposed to extend to the second non-display area PH, and the embodiments of the present specification are not limited thereto.

A fifth routing line 50 can be formed in the same or substantially same process as the connection electrode 240 on the first planarization layer 170 disposed to extend to the second non-display area PH, and the embodiments of the present specification are not limited thereto.

The first routing line 20, the second routing line 30, the third routing line 31, the fourth routing line 40, and the fifth routing line 50 can be electrically connected and disposed to overlap at least partially in the routing line area RK, but are not limited thereto.

Gate lines of the sub-pixels of the display area AA can be connected to the first routing line 20, the second routing line 30, and the third routing line 31 and can also be electrically connected in the second non-display area PH, and data lines of the sub-pixels can be connected to the fourth routing line 40 and the fifth routing line 50 and can also be electrically connected in the second non-display area PH.

In the routing line area RK, the touch lines formed in the same or substantially same material and same or substantially same process as the first touch electrode 810 and the second touch electrode 830 can be formed to electrically connect the touch driving signal of the display area AA and transmit the touch driving signal to another area of the display area AA through the second non-display area PH.

The first pattern structure PT1 and the second pattern structure PT2 are disposed to surround the through hole H. The first pattern structure PT1 and the second pattern structure PT2 can be formed of a lower pattern PTa and an upper pattern PTb. The lower pattern PTa can be simultaneously made of the same or substantially same material as the fourth insulating layer 160. The upper pattern PTb can be simultaneously made of the same or substantially same material as the second planarization layer 180. However, the material and number of layers of the insulating layers of the first pattern structure PT1 and the second pattern structure PT2 are not limited thereto.

In addition, a plurality of the first pattern structures PT1 or the second pattern structures PT2 can be disposed to be spaced a predetermined distance from each other.

The first pattern structure PT1 and the second pattern structure PT2 can reduce or prevent moisture from penetrating the display area AA through the light emitting element layer 610 that is vulnerable to moisture penetration.

A width of a lower surface of the upper pattern PTb disposed above the lower pattern PTa of the first pattern structure PT1 or the second pattern structure PT2 is larger than that of an upper surface of the lower pattern PTa.

The light emitting element layer 610 disposed on an upper surface and side surfaces of the upper pattern PTb is not formed on side surfaces of the lower pattern PTa due to a separation space between the lower surface of the upper pattern PTb and the side surfaces of the lower pattern PTa and thus can be disconnected by the plurality of pattern structures PT.

The hole dam HDM can be disposed between the first pattern structure PT1 and the second pattern structure PT2.

The hole dam HDM can reduce or prevent the second encapsulation layer 720 from overflowing into the through hole H. At least one hole dams HDM can be disposed between the first pattern structure PT1 and the second pattern structure PT2.

The hole dam HDM can be formed by stacking a first dam layer DA1, a second dam layer DA2, a third dam layer DA3, and a fourth dam layer DA4 that are formed in the same or substantially same process and the same or substantially same material as the fourth insulating layer 160, the second flattening layer 180, the bank 190, and the spacer 191, and the embodiments of the present specification are not limited thereto.

Due to the hole dam HDM, the second encapsulation layer 720 can be arranged to overlap with a portion of the second pattern structure PT2 and the hole dam HDM.

The third encapsulation layer 730 can be disposed to extend to the routing line area RK, the first pattern structure PT1, the dam part DM, and the second pattern structure PT2 of the second non-display area PH and can be abutting or in contact with the first encapsulation layer 710 on the upper surfaces or side surfaces of the plurality of patterns PT of the first pattern structure PT1.

The touch buffer layer 800 and the touch insulating layer 820 can be disposed to extend from the routing line area RK, the first pattern structure PT1, the hole dam HDM, and the second pattern structure PT2 of the second non-display area PH to the third encapsulation layer 730.

Referring to FIG. 4, the first routing line 20, the second routing line 30, and the third routing line 31 can be disposed sequentially from the through hole H to the display area AA, and a crack detection line capable of detecting cracks can be disposed in areas between the through hole H and the routing lines 20, 30, and 31. At least one crack detection lines can be disposed, but the present specification is not limited thereto.

The through hole H can be formed in the display area AA of the display panel using a laser at the completion stage of the display panel.

As the laser, a picosecond lasers or femtosecond laser can be used, but the present specification is not limited thereto. A laser amplifies light generated by applying energy to a specific material and uses guided and emitted light and is used for communication, medical, and industrial purposes by having directivity to monochromatic light with characteristics similar to radio waves. Using the laser, a pattern can be formed in a desired area, or a specific area can be easily removed. The laser uses energy to form or remove a pattern, and when the energy of the laser is radiated to a subject, thermal energy melts the subject to form a pattern. The longer the laser is radiated, the more a thermal effect, which is transferred to an area near the portion in which the pattern is formed, can occur. The thermal effect can cause heat to accumulate near the laser radiation area of the subject, thereby burning or deforming a surrounding area that is larger than a set pattern due to the above heat. Due to the characteristic of the laser, when the laser radiation area overlaps or is adjacent to an insulating film, the thermal energy of the laser can also deform the insulating film. Cracks can occur due to the deformation of the insulating film, and the cracks can propagate through the insulating film, causing peeling or causing penetration of moisture and oxygen.

In addition, since the second non-display area PH of the display panel in which the through hole H is formed can be vulnerable to an external impact, cracks can occur due to an external impact and can be transmitted to the display area.

Therefore, in the display apparatus 10 according to one embodiment of the present specification, at least one crack detection pattern parts CPT can be disposed between the through hole H and the routing line area RK to detect cracks and reduce or prevent crack transmission to the second non-display area PH.

FIG. 5 is a cross-sectional view along line 5-5′ in FIG. 4. Referring to FIG. 5, a cross-sectional view is provided which shows a portion in which a first crack detection signal line 201 is connected to a second crack detection signal line 202, a third crack detection electrode 32_3 connected to a third crack detection line 204_3, and the third crack detection line 204_3 connected to the first crack detection signal line 201 through a trench hole TH.

The first crack detection signal line 201 can be disposed on the buffer layer 101 to extend from a side portion of the through hole H to a side portion of the display area AA. The first crack detection signal line 201 can extend to overlap or intersect with the routing line area RK to transmit the crack detection signal to the first non-display area NA and can be formed on a different layer from the routing line.

The first crack detection signal line can be made of the same or substantially same material and formed in the same or substantially same process as the light shielding layer 200.

The first crack detection signal line can be electrically connected to the crack detection electrode 32 and the crack detection line 204 of the crack detection pattern part CPT disposed between the first pattern structure PT1 or the second pattern structure PT2 to detect cracks due to a change in resistance of the crack detection line 204 when the cracks occur.

At least one crack detection pattern parts CPT can be disposed, and a plurality of crack detection electrodes 32 can include a first crack detection electrode 32_1, a second crack detection electrode 32_2, and the third crack detection electrode 32_3, and a plurality of crack detection lines 204 can include a first crack detection line 204_1, a second crack detection line 204_2, and the third crack detection line 204_3.

The first crack detection electrode 32_1, the second crack detection electrode 32_2, and the third crack detection electrode 32_3 can have different lengths, the first crack detection electrode 32_1 can be shorter than the second crack detection electrode 32_2, and the second crack detection electrode 32_2 can be shorter than the third crack detection electrode 32_3.

A resistance value transmitted to the first crack detection signal line 201 can vary depending on the length of the crack detection electrode 32 when cracks occur, thereby identifying positions at which the cracks occur and the extent to which the cracks propagate.

Describing the crack detection pattern part CPT with reference to FIG. 5, the third crack detection electrode 32_3 can be disposed on the second gate insulating layer 150, the lower pattern layer PTa can be disposed on the third crack detection electrode 32_3, and the third crack detection line 204_3 can be disposed on the lower pattern layer PTa.

The third crack detection line 204_3 can be connected to the third crack detection electrode 32_3 through a contact hole formed in the lower pattern layer PTa, and the third crack detection line 204_3 can be connected to the first crack detection signal line 201 through the trench hole TH formed in the lower pattern layer PTa, the second gate insulating layer 150, the third insulating layer 140, the second insulating layer 130, the first gate insulating layer 120, and the first insulating layer 110 to transmit a resistance signal according to the detection of cracks.

The trench hole TH can be formed as a trench-shaped groove in the second gate insulating layer 150, the third insulating layer 140, the second insulating layer 130, the first gate insulating layer 120, and the first insulating layer 110 that are made of an inorganic insulating material and can block propagation directions of cracks when the cracks occur.

A first crack stopper 21 and a second crack stopper 22 can be disposed to overlap the third crack detection electrode 32_3 under the third crack detection electrode 32_3 in a plan view.

The first crack stopper 21 can be disposed on the first gate insulating layer 120 and made of the same or substantially same material and formed in the same or substantially same process as the first gate electrode 220, the second gate line 420, the first capacitor electrode Cst1, and the first routing line 20.

The second crack stopper 22 can be disposed on the second insulating layer 130 and made of the same or substantially same material and formed in the same or substantially same process as the second capacitor electrode Cst2 and the second routing line 30.

The first crack stopper 21 and the second crack stopper 22 can each be metal prevention films that are floating metal layers not electrically connected to other electrodes and lines and can reduce or prevent the propagation of cracks.

A middle pattern PTc can be disposed on the lower pattern PTa and the third crack detection line 204_3. The middle pattern PTc can be made of the same or substantially same material and formed in the same or substantially same process as the first planarization layer 170 and disposed to be spaced apart from the trench hole TH.

A crack detection connection line 51 can be disposed on the middle pattern PTc. The crack detection connection line 51 can include a first crack detection connection line 51_1 connected to the first crack detection line 204_1, a second crack detection connection line 51_2 connected to the second crack detection line 204_2, and a third crack detection connection line 51_3 connected to the third crack detection line 204_3.

Referring to FIG. 5, the third crack detection connection line 51_3 can be formed on the middle pattern PTc at one side of the trench hole HT and the third crack detection line 204_3 and disposed to overlap the third crack detection line 204_3 in a plan view.

Therefore, the first crack stopper 21 and the second crack stopper 22 made of a plurality of inorganic insulating films and metal layers can be disposed to overlap and extend from the crack detection electrode 32 under the crack detection electrode 32, and the crack detection connection line 51 can be disposed to overlap and extend from the crack detection line 204 above the crack detection line 204 to detect the cracks caused by forming the camera hole H and reduce or prevent the propagation to the display area AA.

The third crack detection electrode 32_3, the third crack detection line 204_3, and the third crack detection connection line 51_3 can be electrically connected to transmit the crack detection signal to the first crack detection signal line 201, and the first crack detection signal line 201 can transmit the crack detection signal to the second crack detection line 204_2 through the second crack detection connection electrode 203 so that the crack detection pad part disposed in the first non-display area NA of the display panel can be electrically connected.

At least one crack detection pattern parts CPT can be disposed between the camera hole H and the routing line area RK, the crack detection line 204 of each crack detection pattern part CPT can be electrically connected to the first crack detection signal line 201 to define positions at which crack occur, and a first crack detection pattern part CPT1, a second crack detection pattern part CPT2, and a third crack detection pattern part CPT3 can be disposed around the camera hole H to predict the extent of crack propagation.

A display apparatus according to an embodiment of the present specification can be described as follows.

A display device according to an embodiment of the present disclosure includes a substrate including a display area and a first non-display area surrounding the display area, a plurality of pixels and a camera hole can be disposed in the display area, each of the plurality of pixels can include a plurality of transistors, a second non-display area can be disposed between the display area and the camera hole, the second non-display area can include a crack detection pattern part, the crack detection pattern part can include a crack detection electrode and a crack detection line that surround the camera hole, and the crack detection electrode and the crack detection line can be electrically connected to a crack detection signal line.

According to some embodiments of the present specification, at least one crack detection pattern parts can be disposed in the second non-display area, and the at least one crack detection pattern parts can include a first crack detection pattern part and a second crack detection pattern part that are disposed to be spaced a predetermined distance from each other.

According to some embodiments of the present specification, a hole dam part can be disposed between the first crack detection pattern part and the second crack detection pattern part.

According to some embodiments of the present specification, a first crack detection electrode of the first crack detection pattern part can have a different length from a second crack detection electrode of the second crack detection pattern part.

According to some embodiments of the present specification, the first crack detection electrode can have a shorter length than the second crack detection electrode.

According to some embodiments of the present specification, the crack detection signal line can extend to intersect a routing line area disposed in the second non-display area and transmit the crack detection signal to the first non-display area.

According to some embodiments of the present specification, the plurality of transistors can include a first transistor and a second transistor, and a gate electrode of the second transistor can be disposed on a gate electrode of the first transistor.

According to some embodiments of the present specification, the display apparatus can further include a light shielding layer disposed under the first transistor or the second transistor.

According to some embodiments of the present specification, the crack detection signal line can be made of the same or substantially same material and formed in the same or substantially same process as the light shielding layer.

According to some embodiments of the present specification, the crack detection electrode can be made of the same or substantially same material and formed in the same or substantially same process as the gate electrode of the second transistor.

According to some embodiments of the present specification, the crack detection line can be made of the same or substantially same material and formed in the same or substantially same process as source and drain electrodes of the first transistor and the second transistor.

According to some embodiments of the present specification, the crack detection electrode can be connected to the crack detection line through a contact hole, and at least a portion of the crack detection electrode or the crack detection line can overlap a crack stopper.

A display apparatus according to an embodiment of the present specification can include a display area and a first non-display area surrounding the display area on a substrate, a plurality of pixels and a camera hole can be disposed in the display area, a second non-display area can be disposed between the display area and the camera hole, the second non-display area can at least include a first crack detection pattern part and a second crack detection pattern part, the first crack detection pattern part and the second crack detection pattern part can each include a crack detection electrode and a crack detection line, and lengths of crack detection electrodes of the first crack detection pattern part and the second crack detection pattern part can be different.

According to some embodiments of the present specification, the plurality of pixels can include a plurality of transistors, and the crack detection electrode and the crack detection line can include the same or substantially same material as the gate or source and drain electrodes of the transistor.

According to some embodiments of the present specification, the first crack detection pattern part and the second crack detection pattern part can be electrically connected to a crack detection signal line disposed under the first crack detection pattern part and the second crack detection pattern part.

According to some embodiments of the present specification, the plurality of pixels can include a plurality of transistors and further include a light shielding layer disposed under at least one of the plurality of transistors, and the crack detection signal line can be made of the same or substantially same material and formed in the same or substantially same process as the light shielding layer.

According to some embodiments of the present specification, the crack detection signal line disposed on the substrate, a plurality of insulating layers on the crack detection signal line, a lower pattern layer on the plurality of insulating layers, and a crack detection line disposed on the lower pattern layer can be disposed.

According to some embodiments of the present specification, the crack detection line and the crack detection signal line can be connected through a trench hole formed in the lower pattern layer and the plurality of insulating layers.

According to some embodiments of the present specification, a routing line area can be further disposed between the display area and the second crack detection pattern part, and the display apparatus can further include a third crack detection pattern part between the second crack detection pattern part and the routing line area.

According to some embodiments of the present specification, at least one hole dam parts or a plurality of pattern structures can be disposed between the first crack detection pattern part, the second crack detection pattern part, and a third crack detection pattern part.

According to the display apparatus according to the embodiment of the present specification, it is possible to reduce or prevent cracks that occurs when forming the through hole for a camera and a sensor that are disposed in the display area or occurs near the through hole by an external impact.

According to the display apparatus according to the embodiment of the present specification, it is possible to detect cracks that can be caused by forming the through hole disposed in the display area and where cracks due to an external impact have occurred near the through hole.

The effects of the present specification are not limited to the above-described effects, and other effects that are not described will be able to be clearly understood by those skilled in the art from the following description.

Since the contents of the disclosure described in the above-described limitations to be solved, means to solve the limitations, and effects do not specify the essential features of the claims, the scope of the claims is not limited by the items described in the contents of the specification.

Although the embodiments of the present specification have been described above in more detail with reference to the accompanying drawings, the present specification is not necessarily limited to these embodiments, and various modifications can be carried out without departing from the technical idea of the present specification. Therefore, the embodiments disclosed in the present specification are not intended to limit the technical idea of the present specification, but is intended to describe the same, and the scope of the technical idea of the present specification is not limited by these embodiments. Therefore, it can be understood that the above-described embodiments are illustrative and not restrictive in all aspects.

What is claimed is:

1. A display apparatus comprising:
a substrate including a display area and a first non-display area adjacent to the display area;
a plurality of pixels and a camera hole that are disposed in the display area;
a plurality of transistors included in each of the plurality of pixels; and
a second non-display area between the display area and the camera hole,
wherein the second non-display area includes at least one crack detection pattern part, and
wherein the at least one crack detection pattern part includes:
a crack detection electrode and a crack detection line that surround the camera hole; and
a crack detection signal line electrically connected to the crack detection electrode and the crack detection line.

2. The display apparatus of claim 1, wherein the at least one crack detection pattern part disposed in the second non-display area includes a first crack detection pattern part and a second crack detection pattern part that are disposed to be spaced apart from each other by a predetermined distance.

3. The display apparatus of claim 2, further comprising a hole dam part disposed between the first crack detection pattern part and the second crack detection pattern part.

4. The display apparatus of claim 2, wherein a first crack detection electrode of the first crack detection pattern part has a length different from a length of a second crack detection electrode of the second crack detection pattern part.

5. The display apparatus of claim 4, wherein the first crack detection electrode has a shorter length than the second crack detection electrode.

6. The display apparatus of claim 1, wherein the crack detection signal line extends to intersect a routing line area disposed in the second non-display area and transmits a crack detection signal to the first non-display area.

7. The display apparatus of claim 1, wherein the plurality of transistors include a first transistor and a second transistor, and a gate electrode of the second transistor is disposed on a gate electrode of the first transistor.

8. The display apparatus of claim 7, further comprising a light shielding layer disposed under the first transistor or the second transistor.

9. The display apparatus of claim 8, wherein the crack detection signal line is made of a same material and formed in a same process as the light shielding layer.

10. The display apparatus of claim 7, wherein the crack detection signal line is made of a same material and formed in a same process as the gate electrode of the second transistor.

11. The display apparatus of claim 7, wherein the crack detection line is made of a same material and formed in a same process as a source electrode and a drain electrode of at least one of the first transistor and the second transistor.

12. The display apparatus of claim 1, further comprising a crack stopper disposed to overlap at least a portion of the crack detection electrode or the crack detection line,
wherein the crack detection electrode is connected to the crack detection line through a contact hole.

13. A display apparatus comprising:
a substrate including a display area and a first non-display area adjacent to the display area;
a plurality of pixels and a camera hole that are disposed in the display area; and
a second non-display area between the display area and the camera hole,
wherein the second non-display area includes a first crack detection pattern part and a second crack detection pattern part,
wherein each of the first crack detection pattern part and the second crack detection pattern part includes a crack detection electrode and a crack detection line, and
wherein lengths of the first crack detection pattern part and the second crack detection pattern part are different from each other.

14. The display apparatus of claim 13, wherein each of the plurality of pixels includes a plurality of transistors, and
wherein the crack detection electrode and the crack detection line include a same material as a gate electrode, a source electrode or a drain electrode of one of the plurality of transistors.

15. The display apparatus of claim 13, wherein the first crack detection pattern part and the second crack detection pattern part are electrically connected to a crack detection signal line disposed under the first crack detection pattern part and the second crack detection pattern part.

16. The display apparatus of claim 15, wherein each of the plurality of pixels includes a plurality of transistors and a light shielding layer disposed under at least one of the plurality of transistors, and
wherein the crack detection signal line is made of a same material and formed in a same process as the light shielding layer.

17. The display apparatus of claim 15, further comprising:
the crack detection signal line disposed on the substrate;
a plurality of insulating layers disposed on the crack detection signal line; and
a lower pattern layer disposed on the plurality of insulating layers,
wherein the crack detection line is disposed on the lower pattern layer.

18. The display apparatus of claim 17, wherein the crack detection line and the crack detection signal line are connected through a trench hole formed in the lower pattern layer and the plurality of insulating layers.

19. The display apparatus of claim 13, further comprising:
a routing line area disposed between the display area and the second crack detection pattern part; and
a third crack detection pattern part between the second crack detection pattern part and the routing line area.

20. The display apparatus of claim 13, wherein at least one hole dam part or a plurality of pattern structures are disposed between the first crack detection pattern part, the second crack detection pattern part, and a third crack detection pattern part.
